(19) United States
(12) Patent Application Publication
(10) Pub. No.: US 2021/0391509 A1
(43) Pub. Date: Dec. 16, 2021

(54) Optoelectronic Semiconductor Component and Method for Producing an Optoelectronic Semiconductor Component

(71) Applicant: OSRAM Opto Semiconductors GmbH, Regensburg (DE)

(72) Inventors: Ivar Tangring, Regensburg (DE); Peter Nagel, Regensburg (DE)

(21) Appl. No.: 17/287,889

(22) PCT Filed: Oct. 28, 2019
(86) PCT No.: PCT/EP2019/079378

§ 371 Date: Apr. 22, 2021

(30) Foreign Application Priority Data
Nov. 5, 2018 (DE) 10 2018 127 521.8

(51) Int. Cl. H01L 33/50; H01L 33/10; H01L 27/142; H01L 33/00

(52) U.S. Cl. CPC H01L 33/50; H01L 33/10; H01L 2933/0041; H01L 33/005; H01L 27/142

(57) ABSTRACT

In an embodiment an optoelectronic semiconductor component includes a semiconductor body having an active region configured to generate first electromagnetic radiation, a wavelength conversion element having a conversion region and a sacrificial region, the conversion region configured to convert at least a portion of the first electromagnetic radiation to second electromagnetic radiation and a shaped body in which the semiconductor body and the wavelength conversion element are at least partially embedded and which is at least in places directly adjacent to the semiconductor body and the wavelength conversion element, wherein the conversion region is arranged between the sacrificial region and the semiconductor body, wherein the sacrificial region is transmissive to the first and second electromagnetic radiations, and wherein the shaped body is a reflector for the first and second electromagnetic radiations.

This patent application is a national phase filing under section 371 of PCT/EP2019/079378, filed Oct. 28, 2019, which claims the priority of German patent application 102018127521.8, filed Nov. 5, 2018, each of which is incorporated herein by reference in its entirety.

### TECHNICAL FIELD

An optoelectronic semiconductor component and a method for producing an optoelectronic semiconductor component are specified. The optoelectronic semiconductor component is in particular a radiation-emitting optoelectronic semiconductor component which emits electromagnetic radiation, for example light, during operation.

### SUMMARY

Embodiments provide an optoelectronic semiconductor component which comprises an improved optical contrast between an emission surface and a region surrounding the emission surface.

Further embodiments provide a method for producing an optoelectronic semiconductor component that enables simplified production.

According to at least one embodiment of the optoelectronic semiconductor component, the optoelectronic semiconductor component comprises a semiconductor body having an active region designed for generating electromagnetic radiation. The active region preferably comprises a pn junction, a double heterostructure, a single quantum well (SQW) structure or, particularly preferably, a multiple quantum well (MQW) structure for generating electromagnetic radiation of a first wavelength range.

According to at least one embodiment of the optoelectronic semiconductor component, the optoelectronic semiconductor component comprises a wavelength conversion element having a conversion region and a sacrificial region. The conversion region is configured to convert at least a portion of electromagnetic radiation of the first wavelength range generated in the active region to electromagnetic radiation of a second wavelength range.

The conversion region may be formed with a conversion material, for example an organic or inorganic phosphor, in particular yttrium aluminum garnet (YAG). The conversion region may further be homogeneous, for example in the form of a platelet of said conversion material. Particularly preferably, the conversion region comprises a ceramic conversion material. Furthermore, the conversion region may be formed with a matrix material in which particles of the conversion material are embedded. Furthermore, the particles of the conversion material may be formed as quantum dots. A quantum dot is a structure in which charge carriers are so restricted in their mobility in all three spatial directions that their energy can only be of discrete values. Quantum dots absorb electromagnetic radiation and re-emit it in a desired spectral range.

The sacrificial region is designed to be transmissive to the electromagnetic radiation of the first wavelength range and the electromagnetic radiation of the second wavelength range and forms an emission surface of the optoelectronic semiconductor component. In particular, such a sacrificial region may be translucent or transparent. Through the emission surface, a major part of the electromagnetic radiation generated in the optoelectronic semiconductor component during operation leaves the optoelectronic semiconductor component.

According to at least one embodiment of the optoelectronic semiconductor component, the optoelectronic semiconductor component comprises a shaped body in which the semiconductor body and the wavelength conversion element are at least partially embedded, and which is at least in places directly adjacent to the semiconductor body and the wavelength conversion element.

The shaped body preferably completely covers the side surfaces of the semiconductor body and the side surfaces of the wavelength conversion element. The side surfaces of the semiconductor body and the wavelength conversion element extend transversely to the main extension plane of the semiconductor body and the wavelength conversion element. This means that the semiconductor body and the wavelength conversion element are surrounded peripherally by the shaped body. The shaped body is formed as a reflector for the electromagnetic radiation of the first wavelength range and for the electromagnetic radiation of the second wavelength range.

The sacrificial region and the shaped body each comprise traces of an ablation process on their side facing away from the semiconductor body. Such an ablation process may serve to thin the optoelectronic semiconductor component to a predetermined thickness. The traces of the ablation process on the shaped body may originate from the same ablation process as the traces of the ablation process on the sacrificial region.

Preferably, the shaped body does not protrude the sacrificial region in a direction transverse to the main extension direction of the semiconductor body. In other words, this means that the shaped body and the sacrificial region can be flush with each other in the direction of a normal vector to the main extension plane of the semiconductor body.

In particular, the shaped body is formed with a matrix material in which, for example, particles of titanium dioxide are embedded as a reflective filler material. The reflectivity of the shaped body for the electromagnetic radiation of the first wavelength range and the second wavelength range is in particular 80% and preferably 90%. In particular, assuming an embodiment of the shaped body as a plane-parallel plate having a thickness of 50 μm and sufficiently extended, in particular infinitely extended, with respect to an illuminated surface, the shaped body comprises a reflectivity of at least 70%, preferably of at least 80% and particularly preferably of at least 90% for the electromagnetic radiation of the first and of the second wavelength range. The concentration of, for example, titanium dioxide particles in the shaped body is in particular at least 10 Vol %, preferably at least 15 Vol % and particularly preferably at least 20 Vol %. The shaped body reflects light generated during operation of the optoelectronic semiconductor component back into the semiconductor body and the wavelength conversion element. As a result, coupling out of electromagnetic radiation into the laterally surrounding regions of the semiconductor body and the wavelength conversion element through the shaped body is advantageously reduced or prevented. The contrast between the emission surface of the optoelectronic semiconductor component and the housing body surrounding it is thus advantageously increased.

According to at least one embodiment, the optoelectronic semiconductor component comprises
a semiconductor body comprising an active region designed to generate electromagnetic radiation,
a wavelength conversion element comprising a conversion region and a sacrificial region,
a shaped body in which the semiconductor body and the wavelength conversion element are at least partially embedded and which is at least in places directly adjacent to the semiconductor body and the wavelength conversion element
   wherein
the conversion region is configured to convert at least a portion of electromagnetic radiation of a first wavelength range generated in the active region to electromagnetic radiation of a second wavelength range
the conversion region is arranged between the sacrificial region and the semiconductor body,
the sacrificial region is transmissive to the electromagnetic radiation of the first wavelength range and the electromagnetic radiation of the second wavelength range,
the shaped body and the sacrificial region comprise traces of an ablation process, and
the shaped body is formed as a reflector for the electromagnetic radiation of the first wavelength range and for the electromagnetic radiation of the second wavelength range.

An optoelectronic semiconductor component described herein is based inter alia on the following considerations: a radiating ring can be formed around the emission surface of an optoelectronic semiconductor component. This ring may be caused by scattering effects and waveguiding within the optoelectronic semiconductor component and reduces an optical contrast between the emission surface and the region surrounding the emission surface. For increasing the contrast between the emission surface of the optoelectronic semiconductor component and the material surrounding it, it is desirable to reduce or eliminate the lateral extraction of electromagnetic radiation from the optoelectronic semiconductor component, thus limiting the extraction to the emission region. In other words, extraction of electromagnetic radiation outside the emission region is not desired.

The optoelectronic semiconductor component described herein makes use, inter alia, of the idea of surrounding the emission region of the optoelectronic semiconductor component with a highly reflective shaped body so as to reduce or prevent lateral extraction of electromagnetic radiation from the semiconductor body and from the wavelength conversion element. Further, the reflective shaped body may also be followed by an absorbing housing body to further increase contrast.

According to at least one embodiment of the optoelectronic semiconductor component, the shaped body comprises a width of at least 10 μm, preferably of at least 20 m and particularly preferably of at least 50 μm in a direction parallel to the main extension direction of the semiconductor body. A sufficient width of the shaped body around the semiconductor body is advantageous to ensure a sufficiently high reflectivity. The necessary width depends on the reflectivity of the material in the shaped body. A higher reflectivity advantageously allows a smaller width of the shaped body.

According to at least one embodiment of the optoelectronic semiconductor component, the conversion region is formed with a polysiloxane or a glass in which particles of a conversion material are embedded. Polysiloxane and glass may advantageously comprise high thermal- and UV-radiation resistance.

According to at least one embodiment of the optoelectronic semiconductor component, the sacrificial region is formed with a ceramic, a polysiloxane or with a glass. The sacrificial region is made transmissive to electromagnetic radiation of the first wavelength range and the second wavelength range. Preferably, the sacrificial region is formed in such a way that it can be well removed by means of abrasive mechanical methods, such as grinding or lapping. That is, the sacrificial region is sufficiently hard and comprises only a low lubricating effect to be readily removable by abrasive mechanical methods such as grinding or lapping. In particular, the sacrificial region serves as a grinding stop layer. That is, the sacrificial region has a much greater hardness than the material surrounding it and thus can provide a stop layer in an abrasive removal process. To avoid possible bending due to distortions and different coefficients of thermal expansion in the wavelength conversion element, it is particularly advantageous to form the sacrificial region and the conversion region from the same materials, respectively.

According to at least one embodiment of the optoelectronic semiconductor component, the sacrificial region is formed with a transparent ceramic, a glass or a polysiloxane in which particles of a glass are embedded. Ceramics, polysiloxane and glass are advantageously suitable for an abrasive ablation process and comprise a good transmission of electromagnetic radiation in the visible wavelength range. By embedding transparent glass particles, the thermal expansion coefficient of the polysiloxane can be influenced. As a result, tensions in the wavelength conversion element can be advantageously reduced or avoided.

According to at least one embodiment of the optoelectronic semiconductor component, the wavelength conversion element comprises a transparent compensation region on the side opposite the sacrificial region, wherein the compensation region is preferably formed with the same material or materials as the sacrificial region. In particular, the compensation region comprises the same thermal expansion coefficient and the same thickness as the sacrificial region. Thus, bending of the wavelength conversion element prior to mounting the wavelength conversion element on a semiconductor body due to the different coefficients of expansion of the sacrificial region and the conversion region is reduced or compensated.

According to at least one embodiment of the optoelectronic semiconductor component, the shaped body comprises a concave meniscus-like region. By concave, meniscus-like embodiment is meant a concave curvature of the shaped body as viewed from a point outside the optoelectronic semiconductor component. The shaped body spans from the top edge of the sacrificial region facing away from the semiconductor body to the bottom edge of the semiconductor body. The meniscus-like embodiment of the shaped body corresponds to a concave meniscus to the semiconductor body, the tip of which facing the top edge of the sacrificial region is truncated. The semiconductor body and the wavelength conversion element are preferably completely covered by the shaped body at their side surfaces.

According to at least one embodiment of the optoelectronic semiconductor component, the shaped body is surrounded by a housing body in a direction parallel to the main extension direction of the semiconductor body. The housing body may, for example, be formed with an epoxy or a polysiloxane, in particular silicone. The housing body can be used in particular for mechanical stabilization of the optoelectronic semiconductor component and/or for improved optical separation of the housing body from an emission region.

According to at least one embodiment of the optoelectronic semiconductor component, the material of the housing body comprises an absorption coefficient of at least 70% for electromagnetic radiation of the first and/or second wavelength range. Preferably, the material of the housing body comprises an absorption coefficient of at least 90% for electromagnetic radiation of a first and/or second wavelength range. Due to the absorbing effect of the housing body, an improvement of the contrast between the emission surface and the housing body is achievable. Any small portions of electromagnetic radiation not yet completely reflected by the shaped body can thus be absorbed in the housing body before they can exit the optoelectronic semiconductor component. The requirements for the stability of the housing body with respect to the electromagnetic radiation generated by the semiconductor body or converted by the wavelength conversion element are advantageously reduced, since by means of the reflective shaped body the fraction of the radiation reaching the housing body is reduced.

A method for producing an optoelectronic semiconductor component is further specified. In particular, the method can be used to manufacture a semiconductor component described herein. That is, all features described for the semiconductor component are also disclosed for the method, and vice versa.

According to at least one embodiment of a method for producing an optoelectronic semiconductor component, the method comprises providing a semiconductor body having an active region designed for generating electromagnetic radiation.

According to at least one embodiment of the method, the semiconductor body is arranged on an upper side of a substrate that protrudes the semiconductor body in its main extension direction. For example, the substrate is formed with a semiconductor material. The substrate may be a mechanically supporting component and provide the optoelectronic semiconductor component with its mechanical stability.

According to at least one embodiment of the method, a wavelength conversion element having a conversion region and a sacrificial region is arranged on the side of the semiconductor body facing away from the substrate such that the sacrificial region faces away from the semiconductor body. The wavelength conversion element is configured to convert electromagnetic radiation. The arranging of the wavelength conversion element on the semiconductor body is performed, for example, by means of bonding, soldering or gluing.

According to at least one embodiment of the method, a shaped body is applied to the upper side of the substrate such that the semiconductor body and the wavelength conversion element are at least partially embedded in the shaped body, wherein the shaped body protrudes above the sacrificial region in the vertical direction. The shaped body can be applied in particular by compression molding. The vertical direction corresponds to the direction of a normal vector of the main extension plane of the semiconductor body. The shaped body preferably protrudes beyond the sacrificial region by a maximum of 100 μm, particularly preferably by a maximum of 50 μm. A shaped body protruding beyond the sacrificial region in such a way advantageously allows sufficient tolerance in a subsequent ablation process in which the shaped body and the sacrificial region are at least partially ablated. Furthermore, application of the shaped body by means of, for example, injection molding or compression molding is advantageously facilitated if the shaped body protrudes beyond the sacrificial region, thus creating a gap between the sacrificial region and, for example, a compression molding tool. Due to this gap, the material of the shaped body can be well distributed in the compression mold and damage to the optoelectronic semiconductor component due to a possible collision with the compression mold can be advantageously avoided.

According to at least one embodiment of the method, the removal of at least a part of the shaped body and of the sacrificial region is carried out in vertical direction and an exposure of the sacrificial region is carried out by means of a mechanical and/or a chemical removal process. A thicker shaped body advantageously enables easier application of the shaped body due to larger permissible tolerances, but requires a longer processing time during ablation due to an increased ablation volume of the shaped body.

According to at least one embodiment of the method for producing an optoelectronic semiconductor component, the shaped body is formed with a polysiloxane, in particular silicone, in which filler particles are preferably embedded. Polysiloxanes advantageously comprise a high temperature- and UV-stability. The thermal expansion coefficient of the polysiloxane can be changed by introducing filler particles. Particles of titanium dioxide can be used as filler particles, which advantageously cause a high optical reflectivity of the shaped body.

According to at least one embodiment of the method for producing an optoelectronic semiconductor component, the shaped body is applied by compression molding. A polysiloxane, in particular silicone, is suitable for the compression molding process, since it comprises a low viscosity and thus very good flow properties.

According to at least one embodiment of the method for producing an optoelectronic semiconductor component, the shaped body is applied by means of a dispensing process. In a dispensing method, a specific amount of a material can be applied in a targeted manner in a region by means of a needle. As an alternative to a dispensing method, a jetting method can also be used, wherein a material is ejected from a nozzle at high pressure and can be blown onto a surface. Advantageously, the addition of solvents allows the use of very high titanium dioxide fill levels, as this can reduce the viscosity of the material.

According to at least one embodiment of the method for producing an optoelectronic semiconductor component, arranging of the shaped body is carried out by means of a spray coating process. In a spray coating method, it is possible to use harder polysiloxanes, in particular silicones with high degrees of titanium dioxide filling. The degree of filling describes the proportion of a filler material in a matrix material. A high degree of titanium dioxide filling advantageously produces a high optical reflectivity of the shaped body. This means that a sufficiently high reflectivity can be achieved even with a comparatively thin shaped body. A high degree of titanium dioxide filling is generally accompanied by an inherently disadvantageous high viscosity, which is due to the small size of the titanium dioxide particles. High viscosity makes the material difficult to process. The addition of solvents advantageously allows the use of very high titanium dioxide fill levels, as this can reduce the viscosity of the material. When using a spray coating method, the addition of solvents is particularly easy.

According to at least one embodiment of the method for producing an optoelectronic semiconductor component, arranging of the shaped body is carried out in several layers. Each applied layer may comprise, for example, cracks and gaps caused by shrinkage during curing of the individual layers. The occurrence of cracks and crevices can also be artificially enhanced, for example, by cooling the layers during curing. The cracks and crevices of the respective layer below are filled again by the respective layer above. The unfilled cracks and crevices in the uppermost and last layer are eliminated by the removal process, so that the uppermost layer is subsequently planar and no longer comprises cracks and crevices.

According to at least one embodiment of the method for producing an optoelectronic semiconductor component, the shaped body comprises a concave meniscus-like region and further laterally completely surrounds the semiconductor body and the wavelength conversion element. In other words, the lateral surfaces of the semiconductor body and the wavelength conversion element are completely covered by the shaped body. The concave meniscus-like region of the shaped body spans from the top edge of the sacrificial region facing away from the semiconductor body to the substrate. In particular, the shaped body comprises the shape of a concave meniscus whose tip facing away from the substrate is cut off.

According to at least one embodiment of the method for producing an optoelectronic semiconductor component, the sacrificial region is exposed in such a way that a ridge of the shaped body having a width of at least 10 μm, preferably at least 100 μm, is formed at the edge of the sacrificial region facing away from the semiconductor body. The width of the ridge of the shaped body must be sufficient to ensure a desired high reflectivity of the shaped body. The thickness of this ridge can be varied with the degree of filling of the shaped body with titanium dioxide. A high degree of filling implies a high reflectivity and thus allows a thinner design of this ridge. Due to the meniscus-like embodiment of the shaped body, increased ablation of the sacrificial region produces a wider ridge of the shaped body and vice versa. In other words, the more of the tip of the meniscus-shaped shaped body facing away from the substrate is abraded, the wider the remaining ridge of the shaped body becomes in a direction transverse to the direction of ablation.

According to at least one embodiment of the method for producing an optoelectronic semiconductor component, the shaped body is framed by a housing body by means of an injection molding method or a compression molding method in a direction parallel to the main extension direction of the semiconductor body. The housing body may be formed with an absorbent material. Advantageously, the housing body may also be formed with a UV-unstable material. The greater design freedom in the housing body can also, for example, provide a better match between the thermal expansion coefficient of the housing body and the thermal expansion coefficient of the semiconductor body and, in particular, the substrate.

### BRIEF DESCRIPTION OF THE DRAWINGS

Further advantages and advantageous embodiments and further embodiments of the optoelectronic semiconductor component result from the following exemplary embodiments shown in connection with the figures.

FIGS. 1A to 1C show schematic cross-sections through an optoelectronic semiconductor component described herein according to a first exemplary embodiment in various stages of its manufacturing. The manufacturing is carried out according to an exemplary embodiment of a method described herein;

FIG. 2 shows a schematic cross-section through an optoelectronic semiconductor component described herein according to a second exemplary embodiment;

FIG. 3 shows a schematic cross-section through an optoelectronic semiconductor component described herein according to a third exemplary embodiment;

FIG. 4 shows a schematic cross-section through a wavelength conversion element described herein according to a first exemplary embodiment;

FIGS. 5A to 5C show schematic cross-sections through an optoelectronic semiconductor component described herein according to a fourth exemplary embodiment at various stages of its manufacturing;

FIG. 6 shows a schematic cross-section through an optoelectronic semiconductor component described herein according to a fifth exemplary embodiment; and

FIG. 7 shows a schematic top view of an optoelectronic semiconductor component described herein according to the fifth exemplary embodiment.

Identical, similar or similarly acting elements are given the same reference signs in the figures. The figures and the proportions of the elements shown in the figures with respect to each other are not to be regarded as to scale. Rather, individual elements may be shown exaggeratedly large for better representability and/or for better comprehensibility.

### DETAILED DESCRIPTION OF ILLUSTRATIVE EMBODIMENTS

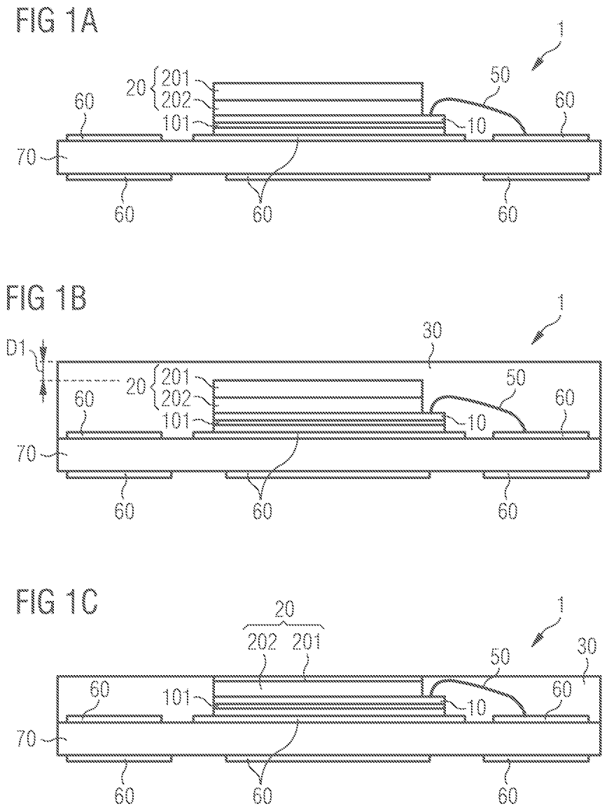

FIG. 1A shows a schematic cross-section through an optoelectronic semiconductor component 1 described herein according to the first exemplary embodiment in a first stage of a method for producing the same. The optoelectronic semiconductor component 1 shown comprises a semiconductor body 10 that comprises an active region 101. The active region 101 includes a pn junction and is configured to emit electromagnetic radiation of a first wavelength range. The thickness and position of the active region 101 in schematic FIG. 1A are only for better representability may differ from the thickness and position in a real component. The semiconductor body 10 is arranged on an electrical connection surface 60 on a substrate 70. The electrical connection surface 60 comprises, for example, a metal or a metal alloy and is used for electrically connecting the semiconductor body 10. A bonding wire 50 and another electrical connection surface 60 are further provided for electrically contacting the semiconductor body 10.

Further, the optoelectronic semiconductor component 1 includes a wavelength conversion element 20 formed with a conversion region 202 and a sacrificial region 201. The wavelength conversion element 20 is arranged on the side of the semiconductor body 10 opposite the substrate 70, so that the conversion region 202 is arranged between the sacrificial region 201 and the semiconductor body 10.

The conversion region 202 is formed with a conversion material, for example, an organic or inorganic phosphor, in particular yttrium aluminum garnet (YAG). The conversion region 202 may further be homogeneous, for example in the form of a platelet of said conversion material. Particularly preferably, the conversion region 202 comprises a ceramic conversion material. Furthermore, the conversion region 202 may be formed with a matrix material in which particles of the conversion material are embedded. Further, the particles of the conversion material may be formed as quantum dots. The conversion region 202 is configured to convert electromagnetic radiation of one of the first wavelength range emitted in the active region 101 during operation of the optoelectronic semiconductor component 1. The conversion region 202 converts at least part of the electromagnetic radiation of the first wavelength range to electromagnetic radiation of a second wavelength range.

In particular, the sacrificial region 201 is formed with a polysiloxane, a transparent ceramic, or glass. The sacrificial region 201 is made transmissive, in particular translucent or transparent, for electromagnetic radiation of the first wavelength range and the second wavelength range.

FIG. 1B shows a schematic cross-section through an optoelectronic semiconductor component 1 described herein according to the first exemplary embodiment in a further stage of a method for producing the same. FIG. 1B is substantially the same as the exemplary embodiment shown in FIG. 1A. In addition, a shaped body 30 is arranged on the substrate 70 to completely surround the semiconductor body 10, the wavelength conversion element 20 and the electrical connection surfaces 60 and the bonding wire 50. The shaped body 30 is formed with a polysiloxane, in particular a silicone, an epoxy or a polymer, and is applied to the substrate 70 by a compression molding process. The shaped body 30 protrudes beyond the sacrificial region 201 in a direction parallel to a normal vector of the main extension plane of the sacrificial region 201 by a protrusion D1, which is at least 100 μm. This protrusion D1 gives the molding tool sufficient tolerance to avoid collision with the optoelectronic semiconductor component 1. The shaped body 30 comprises in particular a filling with titanium dioxide particles. The concentration of titanium dioxide particles in the shaped body 30 is at least 10 Vol %, preferably at least 15 Vol % and particularly preferably at least 20 Vol %. Titanium dioxide comprises a preferably high reflectivity for electromagnetic radiation of the visible wavelength range and thus causes a high reflectivity of the shaped body 30.

FIG. 1C shows a schematic cross-section through an optoelectronic semiconductor component 1 described herein according to the first exemplary embodiment in a further stage of a method for producing the same. FIG. 1C is substantially the same as the exemplary embodiment shown in FIG. 1B. The shaped body 30 and the sacrificial region 201 are removed by a grinding and/or a polishing process such that the sacrificial region 201 of the wavelength conversion element 20 is at least partially exposed. The surface of the shaped body 30 facing away from the substrate 70 and the surface of the sacrificial region 201 facing away from the conversion region 202 lie in a common plane. Thus, the sacrificial region 201 and the shaped body 30 comprise traces of an ablation process. Electromagnetic radiation emitted in the semiconductor body 10 during operation of the optoelectronic semiconductor component 1 and converted in the wavelength conversion element 20 can now exit the optoelectronic semiconductor component 1 unobstructed by the optically transparent sacrificial region 201. The reflective shaped body 30 completely covers the side surfaces of the semiconductor body 10 and the wavelength conversion element 20. Thus, the reflective shaped body 30 also limits electromagnetic radiation exiting laterally from the semiconductor body 10 and the wavelength conversion element 20 and reflects it at least partially back into the semiconductor body 10 and the wavelength conversion element 20. In a top view of the optoelectronic semiconductor component 1, there is thus an advantageously high contrast between the emission region E formed by the sacrificial region 201 and the surrounding shaped body 30. The exiting electromagnetic radiation is thus confined in lateral directions to the region of the sacrificial region 201.

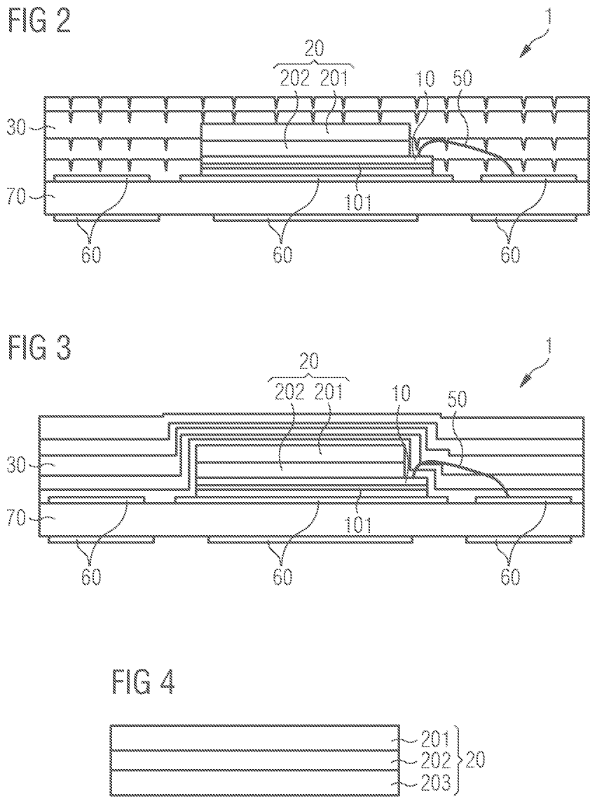

FIG. 2 shows a schematic cross-section through an optoelectronic semiconductor component 1 described herein according to the second exemplary embodiment. The second exemplary embodiment corresponds essentially to the first exemplary embodiment and differs in the structure of the shaped body 30. The shaped body 30 is applied to the substrate 70 in a multi-stage method. In particular, this is a spraying method, a jetting method or a metering method. The individual layers applied in this process each comprise cracks and crevices due to shrinkage during curing of the layers. The cracks and crevices are filled by the respective layer above. Since the cracks are always filled by the respective following layer, only the last applied layer still comprises cracks and crevices. Below the last layer, a solid body without cracks and crevices is formed. These cracks and crevices are tolerable, however, because the upper part of the last layer is removed during a subsequent removal process. Thus, a crack- and crevice-free surface of the shaped body 30 is created, which facilitates the subsequent placement of optical bodies, such as a lens.

FIG. 3 shows a schematic cross-section through an optoelectronic semiconductor component 1 described herein according to the third exemplary embodiment. The third exemplary embodiment is substantially the same as the second exemplary embodiment and differs in the structure of the shaped body 30. The shaped body 30 is applied to the substrate 70 in a multi-step method. A spray method or a metering method with the addition of solvents is used to apply the shaped body 30. By means of such methods, the shaped body 30 can be produced from a polysiloxane having a very high titanium dioxide filling level. Optionally, transparent glass particles may also be added to match the thermal expansion coefficient of the shaped body 30 to the thermal expansion coefficient of the semiconductor body 10 and/or the substrate 70. The inherently disadvantageous high viscosity, caused by a very high titanium dioxide filling level, can be compensated for in these methods by the addition of solvents. The individual layers are deposited in each case partly independently of direction. The superimposed layers reproduce the shape of the underlying semiconductor body 10 and result in an uneven surface. This unevenness is tolerable, however, since the shaped body 30 is planarized in a subsequent ablation process.

FIG. 4 shows a schematic cross-sectional view of a wavelength conversion element 20 described herein in accordance with the first exemplary embodiment. The wavelength conversion element 20 illustrated herein includes a sacrificial region 201, a conversion region 202, and a compensation region 203. The conversion region 202 is located between the compensation region 203 and the sacrificial region 201. The compensation region 203 preferably comprises a material having a thermal expansion coefficient very similar to or the same as the sacrificial region 201. The sacrificial region 201 is formed to be transmissive to electromagnetic radiation of the first wavelength range and electromagnetic radiation of the second wavelength range. The thickness of the sacrificial region 201 and the compensation region 203 are preferably the same. The thickness is considered to be a maximum extension in a direction parallel to a normal vector of the main extension plane of a region. By this embodiment, bending due to a difference in the thermal expansion coefficient between the sacrificial region 201 and the conversion region 202 can be advantageously reduced or prevented. As a result, the conversion element 20 can be fabricated separately before being applied to the semiconductor component 10.

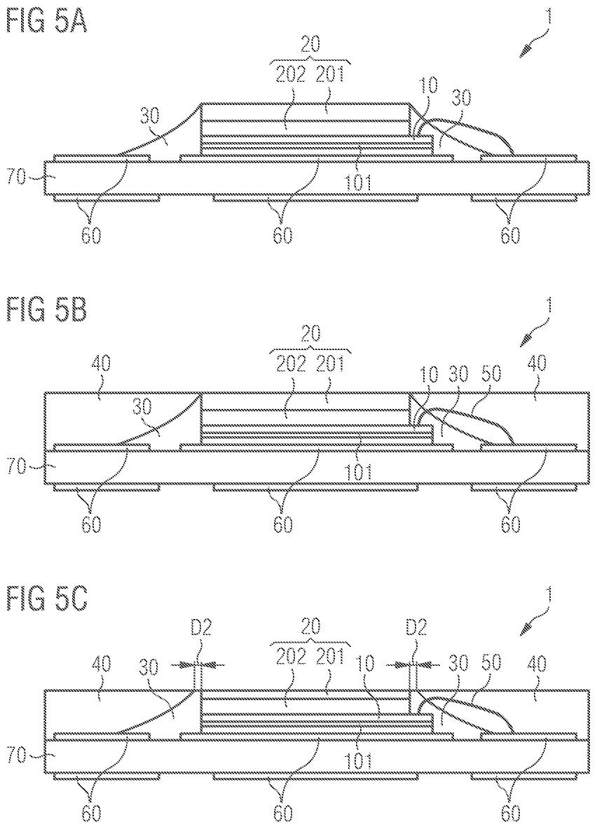

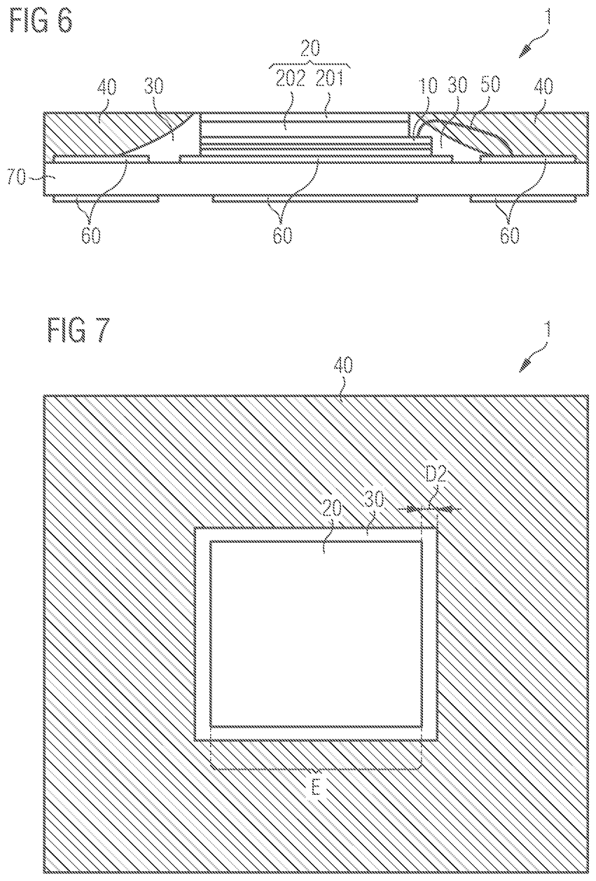

FIG. 5A shows a schematic cross-section through an optoelectronic semiconductor component 1 described herein according to the fourth exemplary embodiment in a first stage of a method for producing the same. The exemplary embodiment shown is substantially the same as the exemplary embodiment shown in FIG. 1A. In addition, the shaped body 30 having a concave meniscus-like shape is attached to the side surfaces of the wavelength conversion element 20 and the semiconductor body 10. A concave meniscus-like shape refers to a concave curvature of a meniscus to an existing surface as viewed from a point outside the optoelectronic semiconductor component 1. The shaped body 30 extends from the edge of the sacrificial region 201 facing away from the substrate 70 to the substrate 70, and the side surfaces of the semiconductor body 10 and the wavelength conversion element 20 are completely covered by the shaped body 30. The shaped body 30 is formed with a polysiloxane, in particular a silicone, in which titanium dioxide is brought in as a filler material. The shaped body 30 comprises here, at a thickness of 50 μm, already a reflectivity of at least 90% for the electromagnetic radiation generated in the optoelectronic semiconductor component 1 during operation. The shaped body 30 is applied by means of a dispensing method or a jetting method. The side surfaces of the semiconductor body 10 and the wavelength conversion element 20 are completely covered by the shaped body 30.

FIG. 5B shows a schematic cross-sectional view of an optoelectronic semiconductor component 1 described herein according to the fourth exemplary embodiment in a further stage of a method for producing the same. The exemplary embodiment shown is substantially the same as the exemplary embodiment shown in FIG. 5A. A housing body 40 is arranged around the shaped body 30. The housing body 40 completely surrounds the shaped body 30. The housing body 40 is applied by a film-assisted molding method, an injection molding method, a compression molding method, a spraying method, a jetting method, or a metering method. The housing body 40 provides, for example, mechanical stabilization of the optoelectronic semiconductor component 1 and/or improvement of the contrast between the emission region E and the housing body 40. The housing body 40 is protected by the shaped body 30 from electromagnetic radiation generated in the optoelectronic semiconductor component 1 during operation.

FIG. 5C shows a schematic cross-sectional view of an optoelectronic semiconductor component 1 described herein according to the fourth exemplary embodiment in a further stage of a method for producing the same. The exemplary embodiment shown is substantially the same as the exemplary embodiment shown in FIG. 5B. The shaped body 30, the housing body 40 and the sacrificial region 201 are removed by a mechanical removal process such that the sacrificial region 201 is exposed, and the upper part of the shaped body 30 forms a ridge having a width of at least 10 μm, preferably at least 50 μm. The ridge width D2 of the meniscus-shaped shaped body 30 results from the maximum extension of the shaped body 30 in a direction parallel to the main extension direction of the substrate 70 on the side of the shaped body 30 facing away from the substrate 70. Since the width of the shaped body 30 increases in a direction starting from the sacrificial region 201 toward the substrate 70, the desired ridge width D2 of the shaped body 30 on the side facing away from the substrate 70 can be adjusted by the ablation volume of the shaped body 30, the housing body 40 and the sacrificial region 201. A larger ablation volume causes a larger ablation depth, resulting in a larger ridge width D2 of the shaped body 30. Depending on the degree of filling of the shaped body 30 with titanium dioxide, a smaller ridge width D2 may be sufficient to ensure sufficient reflectivity of the shaped body 30 for the electromagnetic radiation generated in the optoelectronic semiconductor component 1 during operation.

FIG. 6 shows a schematic cross-section through an optoelectronic semiconductor component 1 described herein in accordance with the fifth exemplary embodiment. The exemplary embodiment shown is substantially the same as the exemplary embodiment shown in FIG. 5C. The shaped body 30 is completely surrounded by a housing body 40 comprising an absorbent filling. For example, the housing body 40 may be formed with a dark plastic, such as an epoxy material, in which absorbent filler materials are embedded. Since the shaped body 30 already comprises a reflective effect, a high reflectivity for the housing body 40 is advantageous, but not mandatory. Furthermore, the proportion of electromagnetic radiation generated in the semiconductor body 10 or the wavelength conversion element 20 during operation of the optoelectronic semiconductor component 1 that can penetrate into the housing body 40 is advantageously low or entirely negligible. This advantageously increases the design freedom for the material of the housing body 40, since materials that are not resistant to radiation, in particular UV-resistant materials, can thus also be used for the latter. As a result, materials with a thermal expansion coefficient better adapted to the substrate 70, the semiconductor body 10 and the wavelength conversion element 20 can also be used, which previously could not be used due to the limiting radiation or UV stability.

FIG. 7 shows a schematic top view of an optoelectronic semiconductor component 1 described herein in accordance with the fifth exemplary embodiment. The wavelength conversion element 20 forms an emission region E through which at least the majority of the electromagnetic radiation generated in the optoelectronic semiconductor component 1 during operation exits the optoelectronic semiconductor component 1. Arranged around the wavelength conversion element 20 in the lateral direction is the shaped body 30. The shaped body 30 surrounds the wavelength conversion element 20 without any gap. The shaped body 30 comprises a ridge width D2 of 100 μm. The shaped body 30 is completely surrounded by the housing body 40 in the lateral direction. Electromagnetic radiation exiting laterally from the semiconductor body 10 and/or the wavelength conversion element 20 is reflected to a predominant part in the shaped body 30, wherein the non-reflected part of the electromagnetic radiation can be absorbed by the material of the housing body 40. Thus, there is an advantageously high contrast between the emission surface E and the shaped body 30 and the housing body 40.

The invention is not limited by the description based on the exemplary embodiments. Rather, the invention encompasses any new feature as well as any combination of features, which particularly includes any combination of features in the patent claims, even if that feature or combination itself is not explicitly specified in the patent claims or exemplary embodiments.

1.-18. (canceled)

19. An optoelectronic semiconductor component comprising:
a semiconductor body comprising an active region configured to generate first electromagnetic radiation of a first wavelength range;
a wavelength conversion element comprising a conversion region and a sacrificial region, the conversion region configured to convert at least a portion of the first electromagnetic radiation to second electromagnetic radiation of a second wavelength range; and
a shaped body in which the semiconductor body and the wavelength conversion element are at least partially embedded and which is at least in places directly adjacent to the semiconductor body and the wavelength conversion element,
wherein the conversion region is arranged between the sacrificial region and the semiconductor body,
wherein the sacrificial region is transmissive to the first and second electromagnetic radiations,
wherein the shaped body and the sacrificial region comprise traces of an ablation process, and
wherein the shaped body is a reflector for the first and second electromagnetic radiations.

20. The optoelectronic semiconductor component according to claim 19, wherein the shaped body comprises a width of at least 10 μm in a direction parallel to a main extension direction of the semiconductor body.

21. The optoelectronic semiconductor component according to claim 19, wherein the conversion region comprises a ceramic a polysiloxane or a glass in which particles of a conversion material are embedded.

22. The optoelectronic semiconductor component according to claim 19, wherein the sacrificial region comprises a transparent ceramic, a polysiloxane or a glass.

23. The optoelectronic semiconductor component according to claim 22, wherein the sacrificial region comprises a polysiloxane in which particles of a transparent glass are embedded.

24. The optoelectronic semiconductor component according to claim 19,
wherein the wavelength conversion element comprises a transparent compensation region on a side of the conversion region opposite the sacrificial region, and
wherein the compensation region comprises the same material as the sacrificial region.

25. The optoelectronic semiconductor component according to claim 19, wherein the shaped body comprises a concave meniscus-like region.

26. The optoelectronic semiconductor component according to claim 25, wherein the shaped body is surrounded by a housing body in a direction parallel to a main extension direction of the semiconductor body.

27. The optoelectronic semiconductor component according to claim 26, wherein a material of the housing body comprises a degree of absorption of at least 70% for the first and second electromagnetic radiations.

28. A method for producing an optoelectronic semiconductor component, the method comprising:
arranging a semiconductor body on an upper side of a substrate which protrudes beyond the semiconductor body in its main extension direction, the semiconductor body comprising an active region for generating first electromagnetic radiation;
arranging a wavelength conversion element having a conversion region and a sacrificial region on a side of the semiconductor body opposite the substrate such that the sacrificial region faces away from the semiconductor body;
applying a shaped body to the upper side of the substrate such that the semiconductor body and the wavelength conversion element are at least partially embedded in the shaped body, the shaped body protruding beyond the sacrificial region in a vertical direction; and
removing at least part of the shaped body and the sacrificial region in the vertical direction and exposing the sacrificial region,
wherein the shaped body comprises a concave curvature as viewed from a point outside the optoelectronic semiconductor component.

29. The method according to claim 28, wherein the shaped body comprises a polysiloxane in which filler particles are embedded.

30. The method according to claim 28, wherein the shaped body is applied by compression molding.

31. The method according to claim 28, wherein applying the shaped body comprises applying the shaped body by a metering process.

32. The method according to claim 28, wherein applying the shaped body comprises applying the shaped body by spraying.

33. The method according to claim 28, wherein applying the shaped body comprises applying the shaped body in several layers.

34. The method according to claim 28, wherein the shaped body comprises a concave, meniscus-like region.

35. The method according to claim 34, wherein the sacrificial region is exposed such that an at least 10 μm wide ridge of the shaped body is formed at an edge of the sacrificial region facing away from the semiconductor body.

36. The method according to claim 34, wherein the shaped body is framed by a housing body in a direction parallel to the main extension direction of the semiconductor body.

37. An optoelectronic semiconductor component comprising:
a semiconductor body comprising an active region configured to generate first electromagnetic radiation of a first wavelength range;
a wavelength conversion element comprising a conversion region and a sacrificial region, the conversion region configured to convert at least a portion of the first electromagnetic radiation to second electromagnetic radiation of a second wavelength range; and
a shaped body in which the semiconductor body and the wavelength conversion element are at least partially embedded and which is at least in places directly adjacent to the semiconductor body and the wavelength conversion element,
wherein the conversion region is arranged between the sacrificial region and the semiconductor body,
wherein the sacrificial region is transmissive to the first and second electromagnetic radiations,
wherein the shaped body and the sacrificial region comprise traces of an ablation process,
wherein the shaped body is a reflector for the first and second electromagnetic radiations, and
wherein the shaped body comprises a concave curvature as viewed from a point outside the optoelectronic semiconductor component.
